(19) United States
(12) Patent Application Publication
(10) Pub. No.: US 2025/0151313 A1
(43) Pub. Date: May 8, 2025

(54) TWO-DIMENSIONAL ELECTRON GAS FIELD-EFFECT TRANSISTOR HAVING SIDE GATES

(71) Applicants: UNIVERSITÉ DE MONTPELLIER, Montpellier (FR); CENTRE NATIONAL DE LA RECHERCHE SCIENTIFIQUE, Paris (FR)

(72) Inventors: Christophe CHAUBET, Teyran (FR); André RAYMOND, Mauguio (FR)

(21) Appl. No.: 18/834,371

(22) PCT Filed: Feb. 1, 2023
(86) PCT No.: PCT/EP2023/052426

§ 371 Date: Jul. 30, 2024

(30) Foreign Application Priority Data
Feb. 1, 2022 (FR) 2200887

(51) Int. Cl. H10D 30/47; H10D 30/01

(52) U.S. Cl. CPC H10D 30/4755; H10D 30/015

(57) ABSTRACT

A two-dimensional electron gas field-effect TEGFET transistor, including a drain, a source and at least one channel included in a heterostructure formed by a stack of at least two semiconductor layers. The TEGFET includes at least two side gates arranged on either side of the at least one channel and each being arranged opposite one side of the channel, the side of the channel having a smaller dimension or thickness of the channel, extending along an axis in which the at least two semiconductor layers are stacked and extending perpendicularly to the length of the channel. The TEGFET does not include a gate positioned below or above the channel with respect to an axis perpendicular to a plane, referred to as the channel plane, in which the channel extends between the source and the drain, the channel plane being perpendicular to the thickness of the channel.

### TECHNICAL FIELD

The present invention belongs to the technical field of two-dimensional electron gas field-effect transistors, referred to as TEGFETs. The operating principle of field-effect transistors is to modulate the current flowing between the source and drain by modifying the voltage applied between the transistor's gate and source. In the case of TEGFETs, source-drain current modulation is achieved by modulating the electron density of the two-dimensional electron gas. The two-dimensional electron gas is confined to a channel in a heterostructure.

TEGFETs feature high electron transport speeds, making them ideal for use in high-frequency devices. TEGFETs are also used for high-power applications, for example in GaN-based devices or components.

The invention relates, in particular but without limitation, to high-frequency transistors. In particular, the invention is applicable to all existing types of TEGFETs and, in particular but not restrictively, to type III-V and III-V-N TEGFETS.

### PRIOR STATE OF THE ART

In view of the above-mentioned fields of application for TEGFETS, their reliability is a decisive criterion.

TEGFETs in the prior art operate by expanding the two-dimensional electron gas across the entire width of the channel, thereby modifying the density and/or geometric distribution of charge carriers in the channel.

This is particularly true of nano-sized transistors. This type of transistor features a channel, for example a nanowire or nanostructure, with the length of the channel, facing the gate(s), wherein conductivity is modulated and/or con-trolled, typically of the order of a few hundred nanometers, generally less than 300 nm. In this case, the length of the channel is less than, equal to or of the same order of magnitude as the mean free path of the electrons in the channel, which is generally, at room temperature, on the order of forty nanometers in gallium arsenide (GaAs), and on the order of a hundred nanometers in gallium nitride (GaN), for example. Also, the transport of electrons in the channel in this type of transistor is ballistic and governed by quantum physics.

Quantum-size transistors of this type therefore have reduced electrical power ratings due to the nanometric size of the channel.

Most TEGFETs in the prior art have an upper gate, located vertically above the channel, with respect to the plane formed by the two-dimensional electron gas, which enables the source-drain current to be controlled by modulating the electron density of the two-dimensional gas by means of an electric field normal to the two-dimensional electron gas. Applying a normal electric field to the two-dimensional electron gas results in depletion of the two-dimensional electron gas over the entire width of the channel, by carrier depletion or enrichment depending on the type and/or architecture of the field-effect transistor, and thus modifies the channel's conductivity.

TEGFETs in the prior art have a number of drawbacks, including, by way of non-limiting examples, gate leakage currents, interface defects, and gate brittleness.

Gate leakage currents are major indicators of the state of a device. They reveal their future deterioration. Improving reliability means controlling leakage current, which is also the source of electronic noise, “generation-recombination” and 1/frequency (f) noise.

Interface defects refer to defects at the semiconductor-gate interface and/or defects at the dielectric-gate interface when a dielectric has been deposited to reduce leakage current. These defects contribute to trapping effects such as transconductance frequency dispersion, collapse of DC drain characteristics, gate and drain transients and microwave power limitation.

The gate's brittleness is due, on the one hand, to the brittleness of the oxide or crystal between the gate and the gas and, on the other, to the fact that the gate is deposited on the surface of the semiconductor without being diffused. The fact that it is simply deposited makes it highly sensitive to electrostatic shock.

The present invention aims to overcome, at least in part, the disadvantages of prior art devices.

A further aim of the invention is to provide a TEGFET:
to overcome the disadvantages of prior art devices, and/or
whose current-voltage characteristics are reliable and reproducible, and/or
with a saturation curve wherein the drain-source current IDS is almost constant and/or does not depend or depends only slightly on the drain-source voltage VDS, and/or
wherein, for a given voltage VDS, the current IDS varies significantly or substantially as the gate bias voltage VGS varies, so that the TEGFET can be operated by varying the voltage VGS, and/or
with little or no gate leakage current, and/or
with reliable and reproducible characteristics over a temperature range from 300 to 1.5 Kelvins, and/or
being insensitive or not very sensitive to the local environment and to interference, such as electromagnetic radiation or ionizing radiation, and/or
usable for high-power applications.

### PRESENTATION OF THE INVENTION

For this purpose, a two-dimensional electron gas field-effect transistor (TEGFET) is proposed. Said TEGFET comprises a drain, a source and at least one channel included in a heterostructure formed by a stack of at least two semiconductor layers, preferably at least two distinct layers or layers of different composition. The at least one channel connects the source and drain along its longest dimension, referred to as the length of the at least one channel.

Said TEGFET comprises at least two side gates arranged on either side of the at least one channel and each arranged opposite one side of the at least one channel, said sides of the at least one channel comprise, or extend along, a smaller dimension of said at least one channel, referred to as the thickness of the at least one channel, the thickness extending along an axis in which the at least two semiconductor layers are stacked and extending perpendicularly to the length of the at least one channel.

Preferably, the TEGFET does not comprise a gate positioned below or above the at least one channel with respect to an axis perpendicular to a plane, referred to as the channel plane, in which the at least one channel extends between the source and the drain, said channel plane being perpendicular to the thickness of the at least one channel and/or being perpendicular to the stacking axis of the at least two semiconductor layers and/or being parallel to the length of the at least one channel.

Preferably, “side of the at least one channel” means a face or surface or interface. Preferably, the side of the at least one channel extends or comprises the thickness and length of the at least one channel.

Preferably, at least one of the side gates faces a side of the at least one channel that is opposite the side facing which at least one other of the side gates faces.

Preferably, the source and drain are comprised in or belong to the same TEGFET layer. Preferably, the layer comprising the drain and source also comprises the at least one channel.

Preferably, the conductivity of the at least one channel and/or the electron density of the two-dimensional gas is modulated and/or controlled, preferably only by the at least two side gates.

Preferably, the at least two side gates are arranged to modulate and/or control the conductivity of the at least one channel and/or the electron density of the two-dimensional gas.

Preferably, the TEGFET does not comprise a gate positioned below or above the channel to modulate and/or control the conductivity of the at least one channel and/or the electron density of the two-dimensional gas.

Preferably, the two-dimensional electron gas is contained and confined in the at least one channel. Preferably, the channel plane is parallel to the plane along which the two-dimensional gas extends.

Preferably, the two-dimensional electron gas extends between an inter-face, lying in a plane parallel to the stacking axis, preferably perpendicular to the channel plane, between the source and the stack of at least two semiconductor layers, and an interface, lying in a plane parallel to the stacking axis, preferably perpendicular to the channel plane, between the drain and the stack of at least two semiconductor layers. Preferably, the two-dimensional electron gas does not extend into the source or drain.

Preferably, the channel extends to the source and drain.

Preferably, the length of the at least one channel corresponds to the largest dimension of the at least one channel and/or the largest distance separating two ends, preferably opposite ends, of the at least one channel.

A “channel plane” means a plane perpendicular to the thickness of the at least one channel.

Preferably, the thickness of the at least one channel is smaller than both the length and width of the at least one channel. The thickness of the at least one channel can be defined as the smallest dimension of the at least one channel and/or as the smallest distance separating two faces, preferably opposite faces, of the at least one channel.

The TEGFET may comprise an even number of side gates. The TEGFET may comprise more than two side gates. The TEGFET may comprise a succession of adjacent side gates, extending along the axis connecting the source to the drain, arranged on either side of the at least one channel. Two adjacent side gates in a succession of side gates can be separated by a trench or recess. The side gates of the succession of side gates can be aligned, two by two, along an axis perpendicular to the axis connecting the source to the drain and perpendicular to the stacking axis.

Preferably, the at least one channel comprises two opposite sides, more preferably two parallel sides.

Preferably, the at least one channel has a width extending along an axis connecting the two sides of the at least one channel.

Preferably, the width of the at least one channel extends along an axis comprised in the channel plane and/or along an axis that is perpendicular to the axis connecting the drain to the source and/or along an axis perpendicular to the length of the at least one channel and/or along an axis perpendicular to the thickness of the at least one channel.

Preferably, the thickness of the at least one channel is shorter than the length of the at least one channel.

Preferably, the TEGFET comprises two separate side gates. Even more preferably, each of the two side gates is independent, in particular from the other of the two side gates. Even more preferably, the two side gates have no portion in common.

Preferably, the two side gates are symmetrical. Preferably, the two side gates are symmetrical with respect to the at least one channel.

Preferably, the two side gates are made of or comprise or consist of a semiconductor material. Preferably, the semiconductor material comprises metal at-oms, preferably diffused metal atoms. Preferably, the semiconductor material, or the portion or part of the semiconductor material, comprising the diffused metal atoms constitutes an ohmic contact.

Preferably, the two side gates and the channel are physically and/or spatially separate elements or components or structures or layers or materials.

Preferably, the two side gates are arranged on either side of the at least one channel in relation to the axis connecting the source and drain.

Preferably, the two side gates extend mainly in a plane in which the at least one channel extends.

The TEGFET may comprise a single channel.

Preferably, the TEGFET may comprise two channels, even more preferably three channels, more preferably four channels and even more preferably five channels. Preferably, the channel planes of the TEGFET channels are parallel to each other. Preferably, the TEGFET channels form a stack along the stacking axis of the at least two semiconductor layers.

Preferably, the face of one of the two side gates on the side of the at least one channel is parallel to the face of the other of the two side gates on the side of the at least one channel.

Preferably, the width of the face of each of the side gates located on the side of the at least one channel corresponds to or is equal to, and is preferably greater than, the thickness of the at least one channel.

The length of the face on the side of the at least one channel of each of the side gates can be defined as the largest dimension of said face and/or as the largest distance between two ends, preferably opposite ends, of said face.

Preferably, the width of the face on the side of the at least one channel of each of the side gates is shorter than the length of said face. The width of the face on the side of the at least one channel of each of the side gates can be de-fined as the smallest dimension of said face and/or as the smallest distance between two ends, preferably opposite ends, of said face.

Preferably, none of the side gates, of the at least two side gates, is in contact with, or has a part or interface in common with, the drain and source.

A larger dimension of the at least two side gates can extend mainly perpendicular or parallel to the axis connecting the gate and the drain.

Preferably, the conductivity of the at least one channel is modulated and/or controlled over a portion or part of the at least one channel. Preferably, the conductivity of the at least one channel is modulated and/or controlled over a segment of the at least one channel. Even more preferably, the segment of the at least one channel wherein conductivity is modulated and/or controlled corresponds to a portion or part of the at least one channel extending over only part of the width and/or over the entire length and/or over the entire thickness of the at least one channel.

Preferably, the segment of the at least one channel wherein the conductivity of the at least one channel is modulated and/or controlled corresponds to a portion or part of the at least one channel extending over a part or portion of the length of the at least one channel. “A part of the length of the at least one channel” may be taken to mean a distance, along the axis connecting the source and drain or along the axis of the length of the at least one channel, less than or equal to the length of the at least one channel. More preferably, the distance or dimension, along the axis connecting the source and the drain, of the segment of the at least one channel wherein the conductivity of the channel is modulated and/or controlled is equal to the length of the face of a side gate, one of the at least two side gates located on the side of the at least one channel or to the length of the face of each of the side gates located on the side of the at least one channel.

The portion or part of the at least one channel wherein conductivity is modulated and/or controlled can be defined as the portion or part of the TEGFET enabling the controlled blocking and/or circulation, preferably controlled, of carriers between drain and source.

The width of the at least one channel can vary along the axis connecting the source to the drain.

Preferably, the term “side”, “lateral”, or “laterally” defines or designates a position or location relative to the axis connecting the drain to the source.

Preferably, a lateral axis can be taken to mean an axis that lies in the channel plane and is perpendicular to the axis connecting the source and drain and perpendicular to the thickness of the at least one channel.

Preferably, the at least two side gates extend along the stacking axis of the at least two semiconductor layers, or along an axis perpendicular to the channel plane, on either side of each channel within the at least one channel. Preferably, the at least two side gates extend along the stacking axis of the at least two semiconductor layers, or along an axis perpendicular to the channel plane, from an outer surface of the TEFGET to the at least one channel. Preferably, the at least two side gates extend, along the stacking axis of the at least two semiconductor layers and along the direction connecting the upper outer surface of the at least two side gates to the at least one channel, beyond each channel, among the at least one channel.

Preferably, none of the side gates is in contact with, nor has a part or interface in common with, the at least one channel.

Preferably, the TEGFET is arranged, and even more preferably, the at least two side gates are arranged, to modulate and/or modify and/or vary the potential in the at least one channel along an axis, known as the lateral axis, comprised in the channel plane and perpendicular to the axis connecting source and drain. Preferably, the TEGFET is arranged to, and even more preferably, the at least two side gates are arranged to modulate and/or modify and/or vary the potential in the at least one channel along the lateral axis by polarizing the at least two side gates with respect to the source.

Preferably, the modulation and/or modification and/or lateral variation of the potential in the at least one channel has the effect of modifying, preferably over one or more portions or parts of the width of the at least one channel, the potential and/or creating a potential gradient laterally in the at least one channel.

Preferably, the modulation and/or modification and/or lateral variation of the potential in the at least one channel has the effect of modulating or modifying or varying in the at least one channel, along the lateral axis, the electron density of the two-dimensional gas and/or the drain-source current density and/or the saturation current.

Preferably, as with FETs in the prior art, the TEGFET according to the invention is arranged so that the potential in at least one channel varies along the channel axis.

Furthermore, according to the invention, the TEGFET, preferably the at least two side gates, are arranged so that the potential is at its maximum at the center of the at least one channel, when the two gates are at the same potential with respect to the source. Preferably, according to the invention, the TEGFET, preferably the at least two side gates, are arranged so that the potential is zero on one or both sides of the at least one channel, when one or both gates are at the same potential as the source.

Preferably, the TEGFET comprises a dielectric disposed between each of the at least two side gates and the at least one channel, or separating each of the side gates from the at least one channel.

Preferably, dielectric means a body or medium with dielectric properties. The effect of the dielectric is to isolate the side gates from the at least one channel.

Even more preferably, the absence of contact or of a part or interface in common between the at least one side gate and the at least one channel, and even more preferably the dielectric disposed between each of the two side gates and the at least one channel, contributes to and/or has the effect of and/or enables the potential in the at least one channel to be modulated and/or modified and/or varied along the lateral axis.

Preferably, the TEGFET comprises an interface between the at least one channel and the dielectric which is opposite or facing or successive or consecutive, preferably directly consecutive, to an interface between the dielectric and one, more than one, or preferably each, of the at least two side gates.

Preferably, the interface between the at least one channel and the dielectric and, respectively, the interface between the at least one channel and a side gate considered among the at least two side gates is a wall or face or side or sur-face of the at least one channel and, respectively, a wall or face or side or sur-face of the side gate considered.

The interface between the at least one channel and the dielectric and, respectively, the interface between the at least one channel and a side gate considered among the at least two side gates can be a common wall or a common face or a common side or a common surface between the at least one channel and the dielectric and, respectively, between the at least one channel and the side gate considered.

Preferably, the dielectric is arranged in the form of a trench or recess.

Preferably, the dielectric is a recess.

Preferably, the recess constitutes a volume extending between one of the at least two side gates and the at least one channel.

Preferably, the recess is delimited laterally, along an axis parallel to the width of the at least one channel, by a face or surface of the at least one channel located opposite or facing the face of a side gate considered among the at least two side gates and the face, located on the side of the at least one channel, of the side gate considered. In this case, preferably, the interface between the at least one channel and the dielectric is formed by the face of the at least one channel opposite the face of the side gate in question. Even more preferably, in this case, the interface between the dielectric and the side gate in question is formed by the face, located on the side of the at least one channel, of the side gate in question.

Preferably, the recess comprises or contains a gas.

In other words, the dielectric can be a gas.

The gas contained or enclosed in the recess may be air.

Preferably, the recess does not comprise or consist of solid material.

Preferably, the at least two side gates, more preferably each of the side gates, comprise and/or are formed and/or composed of one or more semiconductor materials or a layer of one or more semiconductor materials.

Preferably, the at least two side gates, more preferably each of the side gates, comprise and/or consist of and/or are formed of and/or are composed of semiconductor materials or of a stack of one or more semiconductor materials.

Preferably, the semiconductor material(s) making up the at least two side gates comprise(s) metal atoms diffused into the semiconductor material(s), preferably comprise(s) metal atoms diffused into the semiconductor material(s).

Preferably, the drain, source and at least two side gates each comprise a metal layer forming a separate electrical contact. Preferably, the metal layer of the drain, the metal layer of the source and the metal layer of the at least two side gates are respectively located on an upper outer surface of the drain, the source and the at least two side gates. Preferably, the metal layers and upper outer surfaces of the drain, source and at least two side gates constitute, at least in part, preferably only in part, an upper outer surface of the TEGFET.

Preferably, the metal layer has a thickness of 10 to 500 nm. Preferably, the metal layer comprises and/or consists of a eutectic. Preferably, the eutectic comprises and/or consists of gold, germanium and nickel.

Preferably, the TEGFET according to the invention is arranged and/or able to modulate and/or modify and/or vary the potential of the at least one channel along the lateral axis. Preferably, the TEGFET according to the invention is arranged and/or able to modulate and/or modify and/or vary the electron density of the two-dimensional gas and/or the current density of the two-dimensional electron gas along the lateral axis, preferably still over part, preferably over part only, of the width of the at least one channel. Preferably, the TEGFET according to the invention is neither arranged nor capable of applying a constant potential over the entire width of the at least one channel. Preferably, the TEGFET according to the invention is not arranged or capable of varying the electron density of the two-dimensional gas and/or current density uniformly across the entire width of the at least one channel.

Preferably, the at least two side gates, and more preferably each of the side gates, are arranged to modulate and/or modify and/or vary the potential of the at least one channel along the lateral axis. Preferably, the at least two side gates, preferably each of the side gates, are arranged and/or capable of modulating and/or modifying and/or varying the electron density of the two-dimensional electron gas, preferably non-uniformly, across the width of the at least one channel. Preferably, the TEGFET according to the invention is neither arranged nor capable of applying a constant potential over the entire width of the at least one channel. Preferably, the at least two side gates, and even more preferably each of the side gates, are not arranged or capable of generating a depletion of the two-dimensional electron gas and/or current density uniformly across the entire width of the at least one channel.

Preferably, the TEGFET according to the invention, preferably the two side gates, more preferably the arrangement of the two side gates, is not arranged and/or is not capable of transforming the two-dimensional electron gas into a one-dimensional electron gas.

Preferably, and in contrast to nanometer-scale FETs of the prior art, in which operation consists in depleting the channel of its electrons uniformly over the entire width of the channel, in order to modulate the channel's conductivity, the TEGFET according to the invention does not cause the two-dimensional electron gas to be depleted uniformly over the entire width of the at least one channel, but rather generates a non-uniform modulation of the electron density and current over the entire width of the at least one channel.

For this purpose, preferably:
a ratio between the width of the at least one channel and the mean free path of the electrons in the at least one channel, and/or
a ratio between a length of the segment of the at least one channel, facing the at least two side gates, wherein conductivity is modulated and/or con-trolled, and the mean free path of electrons in the at least one channel, and/or
a ratio between a length, preferably a minimum length if the length varies, of the at least two side gates and the mean free path of electrons in the at least one channel,
   is greater than 10, preferably greater than 25, even more preferably great-er than 50, more preferably greater than 60, even more preferably greater than 70, even more preferably greater than 80, even more preferably greater than 90 and particularly advantageously greater than 100.

Preferably, the length of the at least two side gates is taken to mean the dimension of the at least two side gates in a direction parallel to the length of the at least one channel.

Also, the width of the at least one channel and/or the length of the segment of the at least one channel facing the at least two side gates, wherein the conductivity is modulated and/or controlled, and/or the length of the at least two side gates is preferably greater than 0.5 μm, more preferably 1.25 μm, more preferably 2.5 μm, more preferably 3 μm, more preferably 3.5 μm, more preferably 4 μm, more preferably 4.5 μm and most preferably between all and 5 μm.

In contrast to the nanometric FET of the prior art, electron transport in at least one channel of the TEGFET according to the invention is diffusive, that is, the electrons experience inelastic shocks and their movement is controlled by the mean free path of the electrons. However, the inventors have observed that the at least one micrometer-sized channel according to the invention enables TEGFETs to be implemented. In addition, and surprisingly, TEGFETs according to the invention have equivalent or even superior characteristics to nanometer-sized TEGFETs of the prior art (which operate with ballistic transport of electrons in the channel).

Preferably:
the ratio between the width of the at least one channel and the mean free path of the electrons in the at least one channel, and/or
the ratio between the length of the segment of the at least one channel, facing the at least two side gates, wherein conductivity is modulated and/or con-trolled, and the mean free path of electrons in the at least one channel, and/or
the ratio between the length of the at least two side gates and the mean free path of electrons in the at least one channel,
   causes the potential and/or conductivity of the electron gas to vary non-uniformly across the width of the at least one channel. Thus, according to the invention, an equipotential is observed on the sides of the at least one channel, that is, on the lateral edges of the at least one channel, wherein the drain-source current is zero, or virtually zero. It can also be seen that the drain-source current flows mainly in the central part or portion of the at least one channel.

In addition, the width of the at least one channel, on a scale of at least one micrometer, according to the invention, also has the effect of increasing the electrical power of the TEGFET.

Preferably, one of the side gates can be electrically connected to the source.

Preferably, the electrical connection of one of the side gates to the source ensures that the side gate connected to the source has the same potential as that of the source.

A method for modulating the conductivity of at least one channel of a two-dimensional electron gas field-effect transistor, known as a TEGFET, is also pro-posed. The method comprises the step of applying a potential difference between a source and a drain of the TEGFET. The method further comprises the step of applying:
the same potential difference between at least one side gate of the TEGFET, e.g. a first side gate of at least two side gates arranged laterally on either side of the at least one channel of the TEGFET, and the source of the TEGFET, and/or
the same potential on one or each of the side gates and on the source of the TEGFET, and/or
a potential difference between at least one of the side gates of the TEGFET, for example a second or second side gate, arranged laterally on either side of the at least one channel of the TEGFET, or between each of the side gates of the TEGFET, and the source of the TEGFET.

The at least one channel connects the source of the TEGFET and drain along a larger dimension of the at least one channel, known as the length of the at least one channel.

The TEGFET does not comprise a gate positioned below or above the at least one channel with respect to an axis perpendicular to a plane, known as the channel plane, along which the at least one channel extends between the source and the drain. The channel plane is perpendicular to a smaller dimension of the at least one channel, referred to as the thickness of the at least one channel, extending:
along an axis on which are stacked at least two semiconductor layers forming a heterostructure wherein the at least one channel is included, and
perpendicular to the length of at least one channel.

The step of applying the same potential or a potential difference between the at least two side gates and the source and/or applying the same potential or a potential difference between at least one side gate and at least one other side gate may involve modulating and/or modifying and/or varying the potential of at least one side gate relative to the potential of the source and/or the potential of at least one side gate relative to the potential of at least one other side gate.

Preferably, the method for modulating the conductivity of at least one channel of a TEGFET does not comprise the step of modulating and/or modifying and/or varying the potential in the at least one channel and/or the electron density of the two-dimensional gas and/or the current density uniformly across the entire width of the at least one channel.

Preferably, the method for modulating the conductivity of at least one channel of a TEGFET does not comprise a step consisting in applying a constant potential across the entire width of the at least one channel.

Preferably, the method for modulating the conductivity of at least one channel comprises the step of modulating and/or modifying and/or varying the potential and/or conductivity in the at least one channel along an axis, known as the lateral axis, comprised in the channel plane and perpendicular to the axis connecting the source and drain, by applying the same potential difference between at least one of the side gates and the source and/or by applying the same potential to one or each of the side gates and the source and/or by applying a potential difference between at least one of the side gates, or between each of the side gates, and the source.

The step of modulating and/or modifying and/or varying, along the lateral axis, the electrostatic potential in the at least one channel may further comprise the step of modulating and/or modifying and/or varying the potential of the at least two side gates with respect to the source potential and/or the potential of at least one side gate with respect to the potential of at least one other side gate.

The step of modulating and/or modifying and/or varying the potential of the at least two side gates with respect to the source potential and/or the potential of at least one side gate with respect to the potential of at least one other side gate may cause or have the effect of modulating and/or modifying and/or varying the electrostatic potential in the at least one channel along the lateral axis.

Preferably, the step of modulating and/or modifying and/or varying, spatially along the lateral axis, the electrostatic potential in the at least one channel, has the effect of modulating and/or modifying and/or varying the drain-source current and/or the saturation current of the TEGFET.

The method for modulating the conductivity of at least one channel may comprise the step of modulating and/or modifying and/or varying the potential in the at least one channel and/or the conductivity of the two-dimensional electron gas non-uniformly across the width of the at least one channel, preferably across only part of a width of the at least one channel, and/or the width of the at least one channel extends along an axis perpendicular to the length of the at least one channel and perpendicular to the thickness of the at least one channel, by applying the same potential difference between at least one side gate and the source and/or by applying the same potential to one or each of the side gates and the source and/or by applying a potential difference between at least one of the side gates, or between each of the side gates, and the source.

The step of modulating and/or modifying and/or varying the electron density of the two-dimensional gas on only part of the width of the at least one channel may further comprise the step of modulating and/or modifying and/or varying the potential of the at least two side gates with respect to the source potential and/or the potential of at least one side gate with respect to the potential of at least one other side gate.

The step of modulating and/or modifying and/or varying the potential of the at least two side gates with respect to the source potential and/or the potential of at least one side gate with respect to the potential of at least one other side gate may cause or have the effect of modulating and/or modifying and/or varying the electron density of the two-dimensional gas over at least part of the width of the at least one channel.

Preferably, the process for modulating the conductivity of at least one channel does not comprise the step of transforming the two-dimensional electron gas into a one-dimensional electron gas.

The method of modulating the conductivity of a channel of a TEGFET ac-cording to the invention is preferably implemented by the TEGFET according to the invention. Preferably, the TEGFET according to the invention is particularly suitable, preferably even specially designed, for implementing the method according to the invention. Preferably, the method according to the invention is particularly suitable, preferably even specially designed, to be implemented by the TEGFET according to the invention. Thus, any feature of the method for modulating the conductivity of a channel of a TEGFET according to the invention can be integrated into the TEGFET according to the invention and vice versa.

According to the invention, a method for manufacturing a TEGFET, preferably the TEGFET according to the invention, is also proposed. The manufacturing method comprises a single annealing step to form, simultaneously in a single step, distinct ohmic contacts between:
a first metal layer, intended to form an electrical contact, and a drain of the TEGFET, and
a second metal layer, intended to form an electrical contact, and a source of the TEGFET, and
a third metal layer, intended to form an electrical contact, and at least two side gates of the TEGFET, arranged laterally on either side of at least one channel of the TEGFET.

Preferably, the first, second and third metal layers are upper outer layers. Preferably, the first, second and third metal layers are arranged on a upper layer of a stack of at least two layers of semiconductor materials, forming a hetero-structure which comprises the at least one channel intended to form the drain, the source, and the at least two side gates.

Preferably, the single annealing step of the method according to the invention also consists in simultaneously forming, in a single step, the drain, the source and the at least two side gates by diffusion of metal atoms, preferably along a stacking axis of the at least two layers of semiconductor materials:
of the first metal layer in the stack of at least two semiconductor material layers, and
of the second metal layer in the stack of at least two semiconductor material layers, and
of the third metal layer in the stack of at least two semiconductor material layers.

The annealing step can be defined as a single step of forming the ohmic contacts simultaneously in a single operation.

Preferably, the first, second and third metal layers are distinct, independent layers.

Preferably, the metal atoms of the metal layers diffuse into the stack of at least two semiconductor material layers forming the drain, the source and, in particular, the at least two side gates by a distance of more than 50 nm, preferably 100 nm, even more preferably 150 nm, more preferably 200 nm, even more preferably 250 nm and/or by a distance of less than 400 nm, even more preferably 350 nm, even more preferably 300 nm. Preferably, the metal atoms of the metal layers diffuse from an upper outer surface of the drain, source and, in particular, each of the at least two side gates and along a stacking axis of the at least two semiconductor layers.

Preferably, the metal atoms of the metal layers diffuse from the upper outer surface of the drain, the source and, in particular, the at least two side gates, into the stack of at least two layers of semiconductor material by a distance at least equal to or greater than a distance separating:
the upper outer surface of the upper layer of the stack of at least two semiconductor layers, and
the channel.

Preferably, the distance between the upper outer surface of the upper layer of the stack of at least two semiconductor layers and the channel is parallel to the stack axis and/or perpendicular to a plane, known as the channel plane, along which the at least one channel between the source and drain extends.

The TEGFET according to the invention is preferably implemented by the manufacturing method according to the invention. Preferably, the manufacturing method according to the invention is particularly suitable, preferably even specially designed, for implementing the TEGFET according to the invention. Thus, any feature of the manufacturing method according to the invention can be integrated into the TEGFET according to the invention and vice versa.

### DESCRIPTION OF FIGURES

Other benefits and features shall become evident upon examining the detailed description of entirely non-limiting embodiments and implementations, and from the following enclosed drawings:

FIG. 1a) is a schematic oblique-view representation of a prior art TEGFET, and FIG. 1b) is a schematic plan-view representation of a prior art TEGFET,

FIG. 2a) is a schematic oblique-view representation of an embodiment of a TEGFET according to the invention, and FIG. 2b) is a schematic plan-view representation of the embodiment of the TEGFET according to the invention shown in FIG. 2a),

FIGS. 3a) and 3b) are schematic side-view representations of two embodiments of a TEGFET according to the invention,

FIG. 4 is a schematic side-view representation of an embodiment of a multi-channel TEGFET according to the invention,

FIG. 5 is a schematic plan-view representation of a TEGFET wherein a side gate is electrically connected to the source,

FIG. 6a) is a schematic oblique-view representation the channel of a prior art TEGFET in the absence of upper-gate polarization, FIG. 6b) is a schematic oblique-view representation of the channel of a prior art TEGFET in the presence of upper-gate polarization, and FIG. 6c) is a graph showing the evolution of the drain-source potential in the channel along the lateral axis of a prior art TEGFET in the presence of upper-gate bias,

FIG. 7a) is a schematic oblique-view representation of the channel of a TEGFET according to the invention in the absence of polarization of the side gate(s), FIG. 7b) is a schematic view of the channel of a TEGFET according to the invention in the presence of polarization in one or more side gates, and FIG. 7c) is a graph showing the evolution of the drain-source potential in the channel along the lateral axis of a TEGFET according to the invention in the presence of polarization in or more upper gates,

FIGS. 8a) and 8b) are schematic representations of a TEGFET according to the invention, respectively, before the annealing step and after the annealing step,

FIGS. 9a) and 9b) are schematic plan-view representations of a TEGFET according to the invention featuring two different channel geometries,

FIG. 10a) is a graph showing the evolution of drain-source current versus drain-source voltage for different gate-source voltages at a temperature of 300 K of the TEGFET shown in FIG. 9a), FIG. 10b) is a graph showing the evolution of the potential in the channel along the lateral axis at the source end of the channel as a function of the drain-source voltage for a TEGFET temperature of 300 K shown in FIG. 9b), and FIG. 10c) is a graph showing the evolution of the potential in the channel along the lateral axis at the drain end of the channel as a function of the drain-source voltage for a TEGFET temperature of 300 K shown in FIG. 9b),

FIG. 11 is a graph showing the evolution of drain-source current versus drain-source voltage for different gate-source voltages at a temperature of 300 K of the TEGFET shown in FIG. 9b) comprising a δ-doped layer, located at a distance of 2 nm from the GaAS/GaAlAs interface of the TEGFET, comprising Berylium atoms, having an acceptor role, at a density of 4.10⁻¹⁰·cm⁻²,

FIG. 12 is a graph showing the evolution of drain-source current versus drain-source voltage for different gate-source voltages at a temperature of 1.5 K of the TEGFET showed in FIG. 9b) comprising a δ-doped layer, located at a distance of 2.5 nm from the GaAS/GaAlAs interface of the TEGFET, comprising Berylium atoms, having an acceptor role, at a density of 8.10⁻¹⁰·cm⁻².

### DESCRIPTION OF THE EMBODIMENTS

The embodiments are described below are in no way limiting, and in particular, it is possible to consider variants of the invention that comprise only a selection of the features disclosed, in isolation from the other features disclosed (even if that selection is isolated within a phrase comprising other features), if this selection of features is sufficient to confer a technical benefit or to differentiate the invention with respect to the prior state of the art. This selection comprises at least one preferably functional feature which lacks structural detail, or only has a portion of the structural details if that portion only is sufficient to confer a technical benefit or to differentiate the invention with respect to the prior state of the art.

With reference to FIG. 1, a conventional TEGFET from the prior art is shown. This TEGFET comprises a stack of at least two semiconductor layers 21, 22, a drain 3, a source 4, a channel 6 and a upper outer metal gate 50 formed from a metal layer.

Many TEGFETs in the prior art comprise a gate made of a metal deposited on semiconductor layer 21 (commonly known as a Schottky gate) without diffusion from the upper outer metal gate 50 to layer 21 and channel 6. Other TEGFETs in the prior art comprise a dielectric to electrically isolate the upper out-er metal gate 50 from the layer 21 and the channel 6.

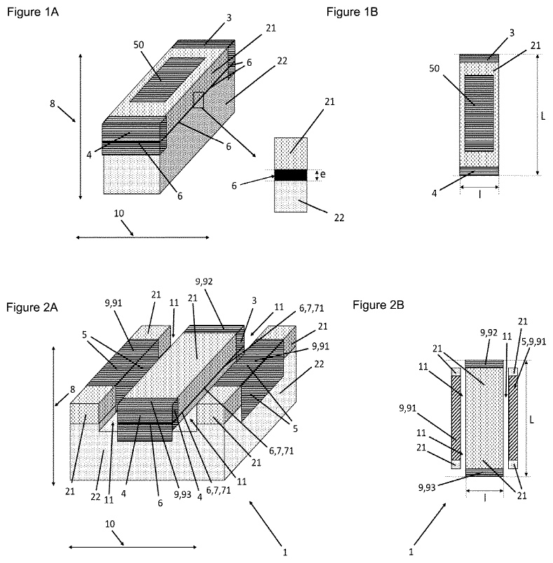

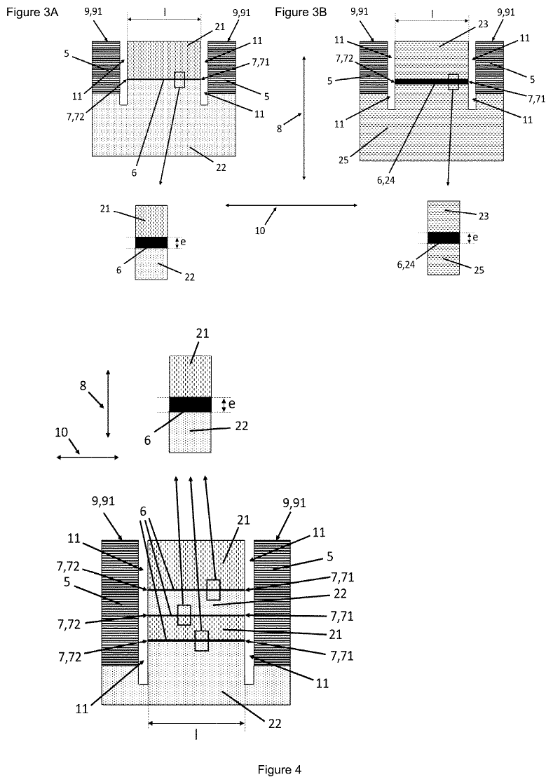

With reference to FIGS. 2 and 3, we present an embodiment of the TEGFET 1 according to the invention. The TEGFET 1 according to the embodiment comprises a drain 3, a source 4 and at least one channel 6, a single channel 6 in the embodiment shown, included in a heterostructure formed by a stack of at least two semiconductor layers 21, 22. The channel 6 connects the source 4 and drain 3 along its longest dimension, L.

The TEGFET 1 comprises at least two side gates 5 each arranged on opposite sides of the at least one channel 6. As shown, the TEGFET 1 comprises two side gates 5 on either side of the channel 6. Each of the side gates 5 faces a different lateral side 7, 71, 72 of the channel 6 from among two lateral sides 7, 71, 72 of the channel 6. The lateral side 7, 71, 72 of the channel 6 comprises the thickness, e, of the channel 6, which is the smallest dimension of the channel 6. The thickness e of the channel 6 extends along a stacking axis 8 of the at least two semiconductor layers 21, 22 and runs perpendicular to the length L of the channel 6. The lateral side 7, 71, 72 of the channel 6 also comprises the length L of the channel 6. The lateral side 7, 71, 72 of the channel 6 is a surface or inter-face that extends along the length L of the channel 6 and along the thickness e of the channel 6.

The TEGFET 1 does not comprise a lower gate positioned below or an upper gate 50 positioned above the channel 6 with respect to an axis 8 perpendicular to the channel plane along which the channel 6 extends. The channel plane is perpendicular to the thickness e of the channel 6. In addition, the stacking axis 8 is perpendicular to the channel plane. In other words, the TEGFET 1 according to the invention does not comprise a lower gate positioned below the channel 6 along the stacking axis 8 or an upper gate 50 positioned above the channel 6 along the stacking axis 8. The absence of a upper gate avoids all the problems encountered with transistors of the prior art, such as gate leakage currents, interface defects, and gate brittleness.

According to the embodiment, the TEGFET 1 comprises a stack consisting, for example, of a GaAs substrate, a GaAlAs layer with a thickness of between 5 nm and 50 nm, a GaAs layer 22 with a thickness of between 10 nm and 100 nm, which forms the channel, and a GaAlAs layer 21 with a thickness of between 50 nm and 300 nm. In this configuration, channel 6 is located in the GaAs layer at the interface between layers 21 and 22.

The side gates 5 according to the invention, combined with the absence of an upper or lower gate 50, enable the potential in channel 6 to be modulated and/or modified and/or varied along the lateral axis 10. The lateral axis 10 lies in the channel plane and is perpendicular to the axis connecting the source 4 and the drain 3. The lateral axis 10 is also perpendicular to the stacking axis 8.

Unlike the TEGFETs of the prior art, which comprise an upper 50 or lower gate and which, as shown in FIGS. 6a), b) and c), therefore modify the electron density of the two-dimensional electron gas over the entire width, denoted I, of the channel 6; the particular arrangement of the TEGFET 1 according to the invention makes it possible, as shown in FIGS. 7a), b) and c), to modify and modulate the potential in the channel 6 solely along the lateral axis 10. Thus, according to the invention, the drain-source saturation current is controlled by changing the current density in the channel 6, whereas in upper-gate 50 or low-er-gate TEGFETs, it is controlled by uniformly changing the electron density of the two-dimensional electron gas along the entire lateral axis 10.

A method for modulating the conductivity of the channel 6 of the TEGFET 1 according to the invention is also described. The method comprises the step of applying a potential difference between the source 4 and drain 3. The method further comprises the step of applying:
the same potential difference between each of the side gates 5 and the source 4, or
the same potential on one of the side gates 5 and on the source 4, and a potential difference between another of the side gates 5 and the source 4, or
a potential difference between each of the side gates 5 and the source 4.

The potential, identical or different, applied between one or each of the side gates 5 and the source 4 can be zero or non-zero.

The step of applying the same potential or a potential difference between the at least one side gate 5 and the source 4 and/or applying the same potential or a potential difference between at least one side gate 5 and another side gate 5 has the effect of varying the potential in the channel 6 along the side axis 10.

The absence of an upper 50 or lower gate in the TEGFET according to the invention means that the method of modulating the conductivity of the channel 6 does not comprise the step of uniformly varying the density of the two-dimensional electron gas over the entire width I of the channel 6.

The two side gates 5 are made of semiconductor material. The two side gates 5 comprise metal atoms diffused into the semiconductor material. According to the embodiment shown, the two side gates 5 consist of a stack of a GaAs layer 22 with a thickness of between 10 and 100 nm and a GaAlAs layer 21 with a thickness of between 50 and 300 nm. The stack of GaAs/GaAlAs layers on the side gates 5 comprises scattered metal atoms.

Each of the side gates 5 extends along the stacking axis 8 from the upper outer metal layer 9, 91 beyond the channel 6 in the direction connecting the up-per outer metal layer 9, 91 to the channel 6.

The diffused metal atoms extend into the layer stack 21, 22 over a distance of between 100 and 300 nm from the upper outer metal layer 9 in the di-rection connecting the upper outer metal layer 9, 91 to the channel 6.

Also, unlike the upper or lower outer metal gate 50 of TEGFETs in the prior art, the side gates 5 according to the invention are made of semiconductor material comprising diffused metal atoms. In addition, the side gates 5 according to the invention are not outer layers but extend into the structure of the TEGFET 1 along the stacking axis 8. This improves the mechanical strength of the gates. This also has the advantage of considerably increasing the potential applied before damaging the gates. Finally, this also makes it possible to extend the applied potential beyond the width I of the channel(s) 6 and thus obtain an optimum, homogeneous electrical effect across the entire width I of the electron gas.

The drain 3 and source 4 extend along the stacking axis 8 from, respectively, the upper outer metal layer 9, 92 and the upper outer metal layer 9, 93 beyond the channel 6 in the direction connecting the upper outer metal layer 9, 92 to the channel 6 and connecting the upper outer metal layer 9, 93 to the channel 6. The diffused metal atoms extend in the layer stack 21, 22 over a distance of between 100 and 300 nm from, respectively, the upper outer metal layer 9, 92 and the upper outer metal layer 9, 93 beyond the channel 6 in the direction connecting the upper outer metal layer 9, 92 to the channel 6 and connecting the upper outer metal layer 9, 93 to the channel 6.

The upper outer metal layer 9, 91, 92, 93 and the diffused metal atoms are a eutectic comprising gold, germanium and nickel.

According to the invention, none of the side gates 5 is in contact or has a part or interface in common with the channel 6. In addition, the TEGFET 1 comprises a dielectric 11 arranged between each of the side gates 5 and the channel 6. The dielectric 11 is preferably in the form of a recess 11. Even more preferably, the dielectric 11 contained in the recess 11 is a gas. In the non-limiting example shown, the gas is air. The gas may be nitrogen or other gases with dielectric properties.

Each of these features, that is, (i) the absence of contact or of a part or interface in common between the side gates 5 and the channel 6, (ii) the presence of a dielectric disposed between each of the side gates 5 and (iii) the arrangement of the dielectric in the form of a recess, individually contribute to increasing the breakdown voltage, reducing leakage currents and improving the characteristics of the TEGFET 1.

FIGS. 3a) and 3b) show, by way of non-limiting examples, two possible configurations of the TEGFET 1 according to the invention. The two-dimensional electron gas can be confined to:
a heterojunction, shown in FIG. 3a), or
a quantum well, shown in FIG. 3b).

In the case of a heterojunction, the channel 6 is located at the interface between two layers 21, 22 of different semiconductors. In this case, the semi-conductors making up the layers 21, 22 have different band gaps, but belong to the same group. The channel 6 is therefore located in a semiconductor layer, in this case the layer 22, whereon the electrons of the two-dimensional gas are confined and bonded to the heterojunction interface.

In the case of a quantum well, the channel 6 is located in the layer 24 of a semiconductor with a small gap, for example a gap of less than 1 electronvolt (eV), deposited between two layers 23, 25 of the same semiconductor with a large gap, for example a gap greater than 1 eV.

The channel plane is parallel to the plane along which the heterojunction interface, or layer 24 of the small-gap semiconductor in the case of the quantum well, extends.

FIG. 4 shows a configuration wherein the TEGFET 1 comprises multiple channels 6. According to the embodiment shown, the TEGFET 1 comprises 3 channels 6. The channels are superimposed along the stacking axis 8. The channel planes of each channel 6 are parallel to each other. This configuration is made possible by the use of side gates 5 according to the invention. This configuration has the effect of increasing current density.

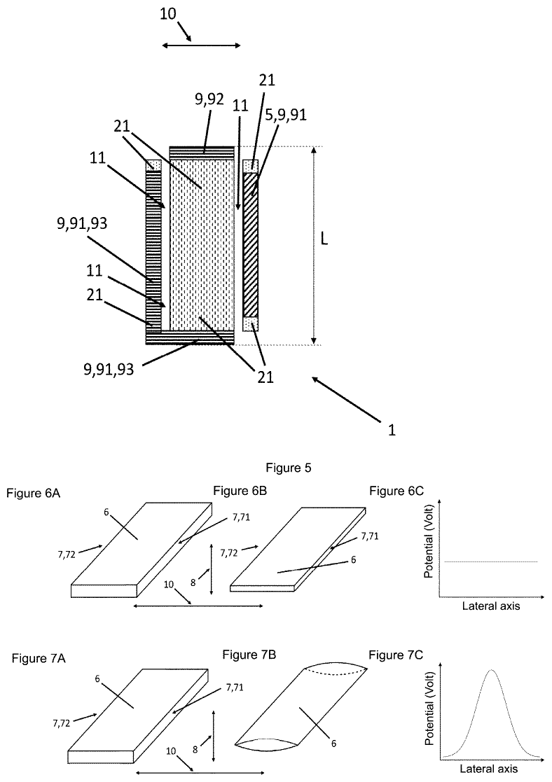

FIG. 5 shows a configuration wherein one of the side gates of the TEGFET 1 is electrically connected to the source 4. In this configuration, one of the side gates 5 and the source 4 are physically connected by the stack of layers 21, 22 and by the upper outer metal layer 9, 91, 93. The source 4 and the side gate 5 connected to the source 4 are therefore at the same potential. In addition, diffused metal atoms extend into the part of the stack of layers 21, 22 connecting the side gate 5 connected to the source 4 and the source 4.

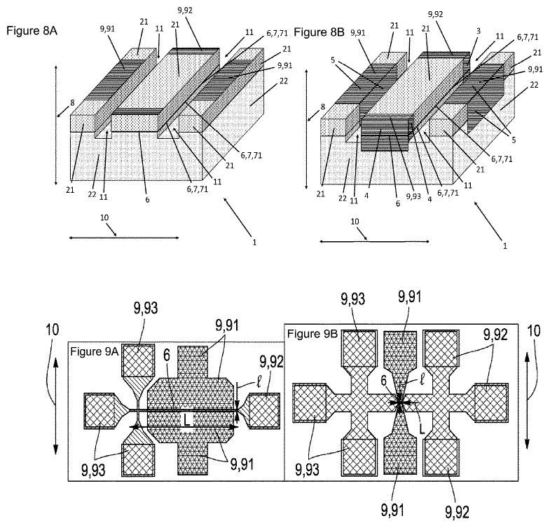

With reference to FIG. 8, a method for manufacturing a TEGFET 1 according to the invention is also described. The manufacturing method comprises a single annealing step to form, simultaneously in a single step, all of the ohmic contacts of the TEFGET 1. These are ohmic contacts between:
the upper outer metal layer 9, 92 of the drain 3, and
the upper outer metal layer 9, 93 of the source 4, and
the upper outer metal layer 9, 91 of each gate 5.

Each of the upper outer metal layers 9, 91, 92, 93 is intended to form an electrical contact through which the TEGFET 1 will be connected to an external power supply.

Prior to the annealing step, the method may comprise the deposition, for example by evaporation, of metal layers 9, 91, 92, 93 on the upper outer surface of the drain 3, source 4 and side gates 5 respectively.

The annealing temperature is between 30° and 450° C. The duration of the annealing step is between 10 seconds and 3 minutes.

The annealing step comprises diffusion or has the effect of diffusing metal atoms from each of the upper outer metal layers 9, 91, 92, 93 into the semiconductor layer 21. Preferably, the annealing time and temperature are chosen so that the metal atoms diffuse from each of the metal layers 9, 91, 92, 93 into the semiconductor layers 21, 22.

The annealing step has the effect of forming an ohmic contact between the upper outer metal layers 9, 91, 92, 93 and the drain 3, the source 4 and, in particular, the side gates 5.

In TEGFETs of the prior art, the diffusion of metal atoms from the upper outer metal layer 50 forming the upper or lower outer metal gate 50 is prohibited to avoid short-circuiting, and/or to avoid lowering the breakdown voltage and/or to limit leakage currents. For this purpose, it is necessary to deposit the upper outer metal layer 50 forming the upper 50 or lower outer metal gate after per-forming the annealing step to form the ohmic contact between the upper outer metal layer 9, 92 of the drain 3 and the upper outer metal layer 9, 93 of the source 4. As a result, the method for manufacturing the TEGFET 1 according to the invention comprises fewer steps, which saves time and energy.

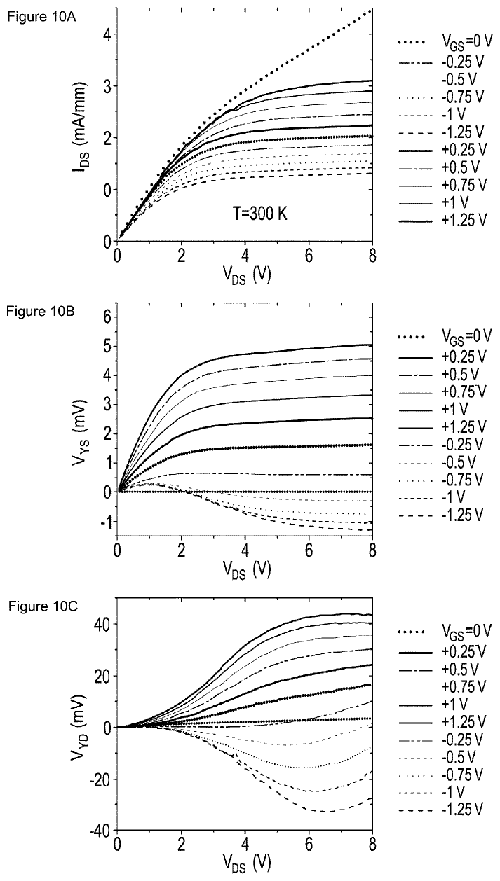

FIGS. 10, 11 and 12 show the performance and features of two different geometries of the channel 6 of the TEGFET 1 according to the invention, as shown in FIG. 9. In the first geometry shown in FIG. 9a), known as TEGFETa) 1, the channel 6 has a length of 730 μm between the source 4 and drain 3 and a thickness of 10 μm between the sides 7, 71 and 7, 72 of the channel 6. In the second geometry shown in FIG. 9b), known as TEGFETb) 1, the channel 6 has a length of 30 μm between the source 4 and drain 3 and a thickness of 10 μm between the sides 7, 71 and 7, 72 of the channel 6. The width and/or length of the channel 6 is limited only by the manufacturing method and equipment used to manufacture the TEGFET 1. The length and/or width of the channel 6 may be several millimeters if the manufacturing method permits.

FIG. 10a) shows the evolution of the drain-source current, denoted IDS, as a function of the drain-source voltage, denoted VDS, for different gate-source voltages, denoted VGS, at a temperature of 300 K for the TEGFETb) 1. The potential difference is applied between one of the two side gates 5 and the source 4. In particular, one of the side gates 5 is grounded and the other is polarized. Note that even when VGS equals zero, a saturation IDS is still observed. When VGS is equal to zero, the side gates 5 are at the same potential as the source 4, which is grounded depending on the embodiment. In addition, for negative polarization of the side gates 5, that is to say for VGS less than zero, IDS decreases and when VGS is positive, IDS increases. This configuration provides the conventional features of a TEGFET.

FIG. 10b) shows the evolution of the potential in the channel 6 along the lateral axis 10 at the source 4 end of the channel 6, denoted VYS, as a function of VDS at a temperature of 300 K for TEGFETb) 1. FIG. 10c) shows the evolution of the potential in the channel 6 along the lateral axis 10 at the drain 3 end of the channel 6, denoted VYD, as a function of VDS at a temperature of 300 K for TEGFETb) 1. The carrier density of the two-dimensional electron gas in this case is 2.4×10¹¹·cm⁻² at 300 K and 1.1×10¹¹·cm⁻² at 1.5 K.

Note that when VGS is equal to 0, neither VYS nor VYD is equal to 0, indicating that even in this case, charges can accumulate along each of the sides 7, 71 and 7, 72 of the channel 6. However, VYS and VYD do not tend towards 0 if the side gates 5 are maintained at the same floating potential, which demonstrates that the side gates 5 strongly modify the potential along the lateral axis 10 and along the length L of the channel 6, even if VGS is equal to 0.

We also note that these results confirm the direct and consequent effect of VGS on the potential in the channel 6 along the lateral axis 10 and on the potential in the channel 6 along the axis along the length L of the channel 6.

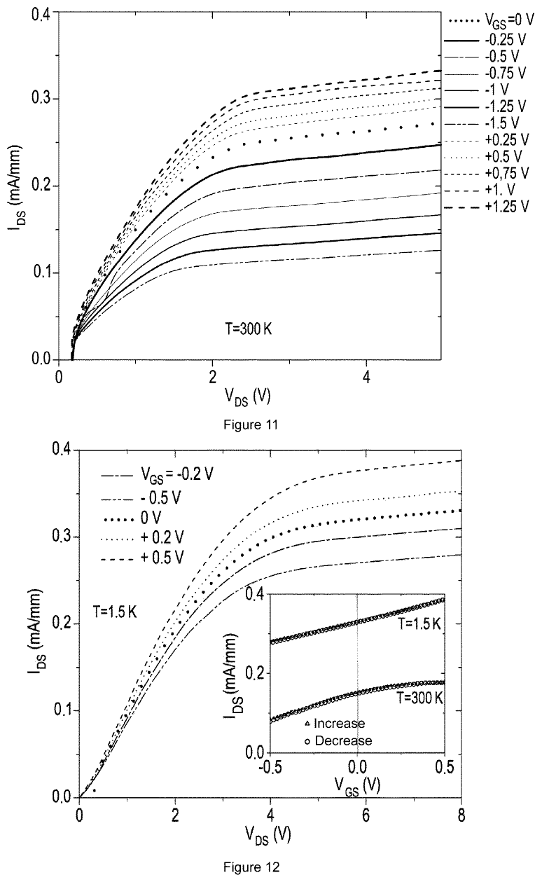

FIG. 11 shows the evolution of the drain-source current, denoted IDS, as a function of the drain-source voltage, denoted VDS, for different gate-source voltages, denoted VGS, at a temperature of 300 K for TEGFETb) 2 with a δ-doped layer comprising berylium atoms, acting as acceptor, at a density of 4×10¹⁰·cm⁻². The δ-doped layer is located at a distance of 2 nm from the GaAS/GaAlAs interface. The carrier density of the two-dimensional electron gas in this case is 2.7.101¹·cm⁻² at 300 K and 1.25.10¹¹·cm⁻² at 1.5 K. This demonstrates that the geometry of the TEGFET 1 has no influence on the characteristics, in particular IDS vs. VDS, of the TEGFET 1 according to the invention. The saturation current IDS and the stability IDS remain unchanged regardless of geometry of the TEGFET 1.

FIG. 12 shows the evolution of the drain-source current, denoted IDS, as a function of the drain-source voltage, denoted VDS, for different gate-source voltages, denoted VGS, at a temperature of 1.5 K for TEGFETb) 2 with a δ-doped layer comprising berylium atoms, acting as acceptor, at a density of 8×10¹⁰·cm⁻². The δ-doped layer is located at a distance of 2.5 nm from the GaAS/GaAlAs interface. The inset in FIG. 12 shows the evolution of the drain-source current, de-noted IDS, during a continuous variation, that is to say without interruption of the voltage variation, of the voltage VGS between −0.5 Volts and +0.5 Volts and then between +0.5 Volts and −0.5 Volts at a temperature of 1.5 K, with a carrier density of the two-dimensional electron gas of 6×10¹⁰·cm⁻², and at a temperature of 300 K, with a two-dimensional electron gas carrier density of 1.6×10¹¹·cm⁻².

We also note that at 1.5 K, the quality of the change in IDS as a function of VDS is maintained compared to 300 K shown in FIGS. 10 and 11. This shows that even at a low carrier density of 8×10¹⁰·cm⁻², TEGFET 1 has low noise and is therefore suitable for low-temperature applications.

Of course, the invention is not limited to the examples just described, and many adjustments can be made to these examples without going beyond the scope of the invention.

Additionally, the various features, forms, variants and embodiments of the invention may be combined with each other in various combinations as long as they are not incompatible or exclusive of each other.

1. A two-dimensional electron gas field-effect transistor, referred to as TEGFET, comprising: a drain; a source and at least one channel comprised in a heterostructure formed by a stack of at least two layers of semiconductor; the at least one channel connects, along its largest dimension, referred to as the length of the at least one channel, the source and the drain; said TEGFET:
comprises at least two side gates arranged on either side of the at least one channel and each arranged opposite one side of the at least one channel, said sides of the at least one channel comprise a smaller dimension of said at least one channel, referred to as the thickness of the at least one channel, extending along an axis in which the at least two semiconductor layers are stacked and extending perpendicularly to the length of the at least one channel; and
does not comprise a gate positioned below or above the at least one channel with respect to an axis perpendicular to a plane, known as the channel plane, along which the at least one channel extends between the source and the drain, said channel plane being perpendicular to the thickness of the at least one channel;
said TEGFET including:
a width of the at least one channel, and/or
a length of a segment of the at least one channel, located opposite the at least two side gates, wherein the conductivity is modulated and/or controlled, and/or
a length of the at least two side gates, the length of the at least two side gates being the dimension of the at least two side gates in a direction parallel to the length of the at least one channel,
is greater than or equal to 500 nanometers.

2. The TEGFET according to claim 1, wherein none of the side gates of the at least two side gates is in contact or has a part or interface in common with the at least one channel.

3. The TEGFET according to claim 1, wherein said at least two side gates are arranged, to modulate and/or modify and/or vary the potential in the at least one channel along an axis, known as the lateral axis, comprised in the channel plane and perpendicular to the axis connecting source and drain.

4. The TEGFET according to claim 1, comprising a dielectric arranged between each of the side gates, of the at least two side gates, and the at least one channel.

5. The TEGFET according to claim 4, wherein the dielectric is arranged in the form of a recess.

6. The TEGFET according to claim 5, wherein the recess comprises a gas.

7. The TEGFET according to claim 1, wherein the at least two side gates are composed of a semiconductor material.

8. The TEGFET according to claim 7, wherein the semiconductor material making up the at least two side gates comprises metal atoms diffused into the semiconductor material.

9. The TEGFET according to claim 1, wherein one of the side gates is electrically connected to the source.

10. A method for modulating the conductivity of at least one channel of a two-dimensional electron gas field-effect transistor, so-called TEGFET, said method comprising the steps of:
applying a potential difference between a source and a drain of the TEGFET;
applying:
the same potential difference between at least one of the side gates of the TEGFET, from among at least two side gates arranged laterally on either side of the at least one channel of the TEGFET, and the source of the TEGFET; and/or
the same potential on one or each of the side gates and on the source of the TEGFET; and/or
a potential difference between at least one of the side gates of the TEGFET and the source of the TEGFET
modulating and/or modifying and/or varying the electron density of the two-dimensional electron gas and/or modulating the current non-uniformly over a width of the at least one channel;
the at least one channel connects, along the largest dimension of the at least one channel, called the length of the at least one channel, the source and the drain of the TEGFET and the TEGFET does not comprise a gate positioned below or above the at least one channel with respect to an axis perpendicular to a plane, called channel plane, in which the at least one channel extends between the source and the drain, said channel plane being perpendicular to the smallest dimension of the at least one channel, called the thickness of the at least one channel, extending along an axis along which are stacked at least two semi-conductor layers forming a heterostructure wherein the at least one channel is comprised and extending perpendicularly to the length of the at least one channel; each of the at least two side gates is arranged opposite a side of the at least one channel, said sides of the at least one channel comprise the thickness of the at least one channel; the width of the channel and/or a length of a segment of the at least one channel, located opposite the at least two side gates, wherein the conductivity is modulated and/or controlled, and/or a length of the at least two side gates is greater than or equal to 500 nm.

11. The method according to claim 10, comprising the step of modulating and/or modifying and/or varying the potential and/or conductivity in at least one channel along a so-called lateral axis lying in the channel plane and perpendicular to the axis connecting source and drain, by applying the same potential difference between at least one of the side gates and the source and/or by applying the same potential to one or each of the side gates and the source and/or by applying a potential difference between at least one of the side gates, or between each of the side gates, and the source.

12. The method according to claim 10, comprising the step of modulating and/or modifying and/or varying the potential in the at least one channel and/or the conductivity of the two-dimensional electron gas non-uniformly along a width of the at least one channel, the width of the at least one channel ex-tends along an axis perpendicular to the length of the at least one channel and perpendicular to the thickness of the at least one channel, by applying the same potential difference between at least one side gate and the source and/or by applying the same potential to one or each of the side gates and the source and/or by applying a potential difference between at least one of the side gates, or between each of the side gates, and the source.

13. A method for manufacturing a two-dimensional electron gas field-effect transistor, referred to as a TEGFET, said manufacturing method comprises a single annealing step for forming, simultaneously in a single step, distinct ohmic contacts between:
a first metal layer, intended to form an electrical contact, and a drain of the TEGFET; and
a second metal layer, intended to form an electrical contact, and a source of the TEGFET; and
a third metal layer, intended to form an electrical contact, and at least two side gates of the TEFGET, arranged laterally on either side of at least one channel of the TEGFET and each arranged facing a side of the at least one channel, said sides of the at least one channel comprise a smaller dimension of said at least one channel, referred to as the thickness of the at least one channel, extending along an axis along which the at least two semiconductor layers are stacked and extending perpendicular to a length of the at least one channel; an annealing time and temperature are chosen so that metal atoms diffuse from each of the metal layers into the semiconductor layers.
